(19) United States
(12) Patent Application Publication
(10) Pub. No.: US 2002/0060372 A1
(43) Pub. Date: May 23, 2002

(54) IC chip

(76) Inventors: Simon Muff, Munich (DE); Christian Hauser, Regensburg (DE)

Correspondence Address: LERNER AND GREENBERG, P.A., Post Office Box 2480, Hollywood, FL, 33022-2480, US

(21) Appl. No.: 10/010,164

(22) Filed: Nov. 13, 2001

Related U.S. Application Data
(63) Continuation of application No. PCT/DE00/01507, filed on May 12, 2000.

(30) Foreign Application Priority Data
May 12, 1999 (DE) 199 22 186.3

(51) Int. Cl. H01L 23/48; H01L 29/40

(52) U.S. Cl. 257/786; 257/734

(57) ABSTRACT

An IC chip is described that has a number of connecting devices, to which a specific predetermined pin assignment is respectively assigned and the pin assignment is provided more than once. The IC chip can be mounted optionally in a standard wiring, resulting from the pin assignment, or in a mirror-image wiring, mirror-inverted in relation to the standard wiring, likewise resulting from the pin assignment. To be able to produce such a chip at low cost and mount it in a simple manner, it is proposed that at least two groups of metallic bonding pads, which are disposed on the upper side or underside of the IC chip, are provided as the connecting devices and that the first group of bonding pads are assigned the standard wiring or standard pin assignment and at least a second group of bonding pads is assigned the corresponding mirror-image wiring or mirror-image pin assignment.

### CROSS-REFERENCE TO RELATED APPLICATION

This application is a continuation of copending International Application No. PCT/DE00/01507, filed May 12, 2000, which designated the United States.

### BACKGROUND OF THE INVENTION

### FIELD OF THE INVENTION

The invention relates to an IC chip having a number of connecting devices to which a specific predetermined pin assignment are respectively assigned. The pin assignment can be provided more than once. The IC is mountable in a standard wiring resulting from the pin assignment or in a mirror-image wiring, mirror-inverted in relation to the standard wiring. Such an IC chip is already known from U.S. Pat. No. 5,502,621.

Integrated circuit (IC) chips are used in a wide variety of applications. They are generally part of highly complex electrical or electronic circuits. The circuits are often realized on printed-circuit boards (PCBs), which are fitted with one or more such IC chips and on which conductor tracks which connect the individual IC chips to one another or to other electrical or electronic components are applied in one or more layers. The IC chips usually have metallic bonding pads, which are connected to the conductor tracks by wire connections (“bonds”) and each of which is assigned a specific predetermined electrical functionality (“pin assignment”). To protect them from being destroyed, the IC chips are generally packaged. Apart from the classic type of connection of the IC chips, in which the bond wires are led through the PCB and soldered to the assigned conductor track on the rear side, today other connection techniques are also used for the insertion of components on PCBs, such as for example surface-mounted technology (SMT) on one or both sides, in which the IC chips are connected by their bonds directly to the conductor tracks, which are located on the same side of the PCB as the IC chips. However, with this mounting or component-insertion technique as well, connections through the PCB or, if multiple layers of conductor tracks are used, from one conductor track layer to another conductor track layer are possible through corresponding holes (“via holes”) in the PCB or in the corresponding layers. To realize equal conductor track lengths (“channel lengths”), for example where both sides of PCBs are fitted with a plurality of identical IC chips, or to avoid or reduce troublesome line crossings (“crossover”) or undesired longitudinal capacitances and inductances where conductor tracks run parallel to one another (“crosstalk”), it has proven to be expedient when mounting a number of identical IC chips on a PCB to use not only IC packages with standard wiring but also IC packages with what is known as mirror-image wiring. With this type of wiring, the electrical functionality of the IC chip is retained, but the wiring is mirror-inverted about a central axis in comparison with the standard wiring.

In the case of the solution, a is chip provided on its upper side with (square) metallic bonding pads (“pads”), which have a specific pin assignment, indicated by the numbering, and which are connected to wiring of an interposer. The wiring have at their free ends bonding points (“balls”), which in each case corresponds to that of the associated bonding pads. The pin assignment of the individual bonding pads on the upper side of the IC chip consequently corresponds exactly to the pin assignment of the corresponding bonding points of the interposer wiring. The wiring is configured in such a way that the free bonding points are disposed in pairs to the left and right of the IC chip. The configuration of the bonding points is a standard wiring or standard pin assignment with the pin assignments on one side of the IC chip and the pin assignments on the opposite side of the IC chip. The configuration of the bonding points on the other hand may respectively be a mirror-image wiring or mirror-image pin assignment, which is mirror-inverted at the central axis of the IC chip in comparison with the standard pin assignment and runs parallel to the row of bonding pads on the upper side of the IC chip. A disadvantage of the known solution is that the IC chips have to be packaged in at least two configurations, that is in the standard configuration and at least in one configuration corresponding “mirror-invertedly” to it. This increases the costs of producing such IC chips and makes it more difficult for PCBs to be fitted with such IC chips, since it must be strictly ensured when mounting the chips that the “correct” package chip, i.e. either the chip in the standard configuration or the chip in the mirror-image configuration, is selected in each case.

The disadvantages are avoided by the IC chip of U.S. Pat. No. 5,502,621. In the case of this chip, disposed in a square package, some of the electrical terminals led out laterally from the package along with their associated pin assignment are provided twice, in such a way that the terminals with the same pin assignment are disposed mirror-invertedly in relation to one another with respect to one of the two central axes lying in the chip plane of the square chip package. The central axes are aligned parallel to the outer edges of the chip package. The positioning of the double pin assignment makes it possible to use the chip both in the standard configuration and in the mirror-image configuration without changing the chip layout. In other words, the (packaged) chip is either a “standard” chip or a corresponding “mirror-image” chip, depending on the type of mounting and positioning on the PCB. With chips of this type it is possible, given the insertion of components on one or both sides of PCBs, for geometrically very simply structured circuit setups to be realized; for example, pairs of chips which are connected to one another on the upper side of the PCB, while being turned by 180 degrees with respect to each other, and are complemented on the underside of the PCB by corresponding pairs of chips, the two pairs of chips being connected to one another by via holes. The inner structure of the packaged IC chip, in particular the internal connection of the actual integrated semiconductor circuit in the package to the electrical terminals led out laterally from the package, is not disclosed in U.S. Pat. No. 5,502,621.

### SUMMARY OF THE INVENTION

It is accordingly an object of the invention to provide an IC chip which overcomes the above-mentioned disadvantages of the prior art devices of this general type, which can be mounted both in the standard configuration and in the mirror-image configuration without changing the chip layout.

With the foregoing and other objects in view there is provided, in accordance with the invention, an integrated circuit (IC) chip. The IC chip contains a chip body having an upper side and an under side. The chip body can be connected optionally to one of a standard wiring configuration for a standard pin assignment and to a mirror-image wiring configuration for a mirror-image pin assignment. The mirror-image wiring configuration is mirror-inverted in relationship to the standard wiring configuration. At least two groups of metallic bonding pads are disposed on the upper side or the under side of the chip body. A first group of the two groups of metallic bonding pads are ordered in the standard pin assignment, and a second group of the two groups of metallic bonding pads are ordered in the mirror-image pin assignment.

The idea on which the invention is based is that the IC chip has at least two groups of metallic bonding pads, which are disposed on the upper side or underside of the IC chip. The first group of bonding pads is assigned the standard configuration wiring or the standard pin assignment and at least a second group of bonding pads is assigned the mirror-image wiring or the mirror-image pin assignment corresponding to the standard wiring and assignment.

A major advantage of the solution is that, depending on the geometrical positioning or alignment of the IC chip in the electrical or electronic circuit (for example on a PCB), the chip can be optionally mounted in a standard wiring, resulting from the pin assignment of the selected group of bonding pads, or in a corresponding mirror-image wiring, resulting from the pin assignment of the other selected group of bonding pads, without the layout of the chip having to be changed for this purpose.

In a first preferred embodiment of the invention, the standard wiring or standard pin assignment is realized by the positioning of the chip in a first position and the mirror-image wiring or mirror-image pin assignment is realized by the positioning of the chip in a second position. In the case of the solution, the two positions of the chip are created in such a way that the second position can be transformed into the first position by rotation of the chip about an axis aligned perpendicularly in relation to the upper side or underside of the chip (and vice versa).

Depending on the spatial configuration of the two groups of bonding pads in relation to one another on the chip, the angle of rotation may be, for example, 90° or 270° or, preferably, 180°.

In a second preferred embodiment of the invention, the standard wiring or standard pin assignment is realized by the positioning of the chip in a first position and the mirror-image wiring or mirror-image pin assignment is realized by the positioning of the chip in a second position. In the case of the solution, the two positions of the chip are created in such a way that the second position can be transformed into the first position by a translational movement of the chip along a first straight line, running parallel to the upper side or underside of the chip (and vice versa).

The advantage of the two embodiments (rotational or translational solution) is that either the standard configuration of the wiring or pin assignment or its mirror-image configuration can be realized by a simple rotation or displacement of the chip in relation to the electrical or electronic circuit. Changing of the chip layout is not required. When mounting such chips on PCBs with the aid of interposers, one and the same interposer type can be used both for the standard configuration and for the mirror-image configuration, i.e. the layout of the interposer also does not have to be changed.

In accordance with an added feature of the invention, given the standard wiring configuration for the standard pin assignment and the mirror-image wiring configuration for the mirror-image pin assignment, the standard pin alignment is realized by the positioning of the chip body in a first position. The mirror-image pin assignment is realized by a positioning of the chip body in a second position and once in the second position can be transformed into the first position by rotation of the chip body about an axis aligned perpendicularly in relation to the upper side or the underside of the chip body or by a translational movement of the chip body along a straight line, running parallel to the upper side or to the underside of the chip body.

In accordance with an additional feature of the invention, the standard wiring configuration and the mirror-image wiring configuration in each case extends on two opposite sides of the chip body over the chip body.

In accordance with a further feature of the invention, a first group of the metallic bonding pads is disposed in a first row and the second group of the metallic bonding pads is disposed in a second row on the chip body. The first row and the second row are disposed next to each other. The metallic bonding pads of the first row and the metallic bonding pads of the second row have within their own row, in each case, a same spacing in relation to directly neighboring bonding pads. The metallic bonding pads of the first row and the metallic bonding pads of the second row each lie along one of two straight lines running parallel to each other. The metallic bonding pads in the first row and the metallic bonding pads in the second row lie directly opposite one another and in each case lie along a further straight line, running perpendicularly in relation to the two straight lines.

In accordance with another feature of the invention, pins of the standard pin assignment of the metallic bonding pads of the first group along the first row are assigned in a same direction as pins of the mirror-image pin assignment of the metallic bonding pads of the second group.

In accordance with a further added feature of the invention, the transformation from the second position of the chip body into the first position, and vice versa, in each case a translational movement transversely in relation to the first and second rows is required.

In accordance with a further additional feature of the invention, the metallic bonding pads of the first group and of the second group are disposed in an alternating manner in a common row. The metallic bonding pads of the first group and of the second group in the common row have in each case a same spacing in relation to directly neighboring bonding pads of the other group respectively. The metallic bonding pads of the first group and of the second group lying in the common row lie along a straight line.

In accordance with another further feature of the invention, the pins of the standard pin assignment of the metallic bonding pads of the first group and pins of the mirror-image pin assignment of the metallic bonding pads of the second group both lying along the common row are assigned in a same direction.

In accordance with an added feature of the invention, the pins of the standard pin assignment of the metallic bonding pads of the first group along the first row are assigned in an opposite direction than pins of the mirror-image pin assignment of the metallic bonding pads of the second group.

In accordance with a concomitant feature of the invention, for a transformation from the second position of the chip body to the first position, and vice versa, in each case a translational movement along the common row is required.

Other features which are considered as characteristic for the invention are set forth in the appended claims.

Although the invention is illustrated and described herein as embodied in an IC Chip, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a plan view of an IC chip from above with wiring in a standard configuration according to the prior art;

FIG. 2 is a plan view of the IC chip from above with wiring in a mirror-image configuration corresponding to the IC chip shown in FIG. 1 according to the prior art;

FIG. 3 is a plan view of another IC chip from above with wiring in the mirror-image configuration corresponding to the IC chip shown in FIG. 1 according to the prior art;

FIG. 4 is a plan view of an advantageous first embodiment of the IC chip according to the invention from above with wiring in the standard configuration;

FIG. 5 is a plan view of the IC chip shown in FIG. 4 with wiring in the mirror-image configuration;

FIG. 6 is a plan view of an advantageous second embodiment of the IC chip according to the invention from above with wiring in the standard configuration;

FIG. 7 is a plan view of the IC chip according to FIG. 6 with wiring in the mirror-image configuration;

FIG. 8 is a plan view of an advantageous third embodiment of the IC chip according to the invention from above with wiring in the standard configuration;

FIG. 9 is a plan view of the IC chip according to FIG. 8 with wiring in the mirror-image configuration.

### DESCRIPTION OF THE PREFERRED EMBODIMENTS

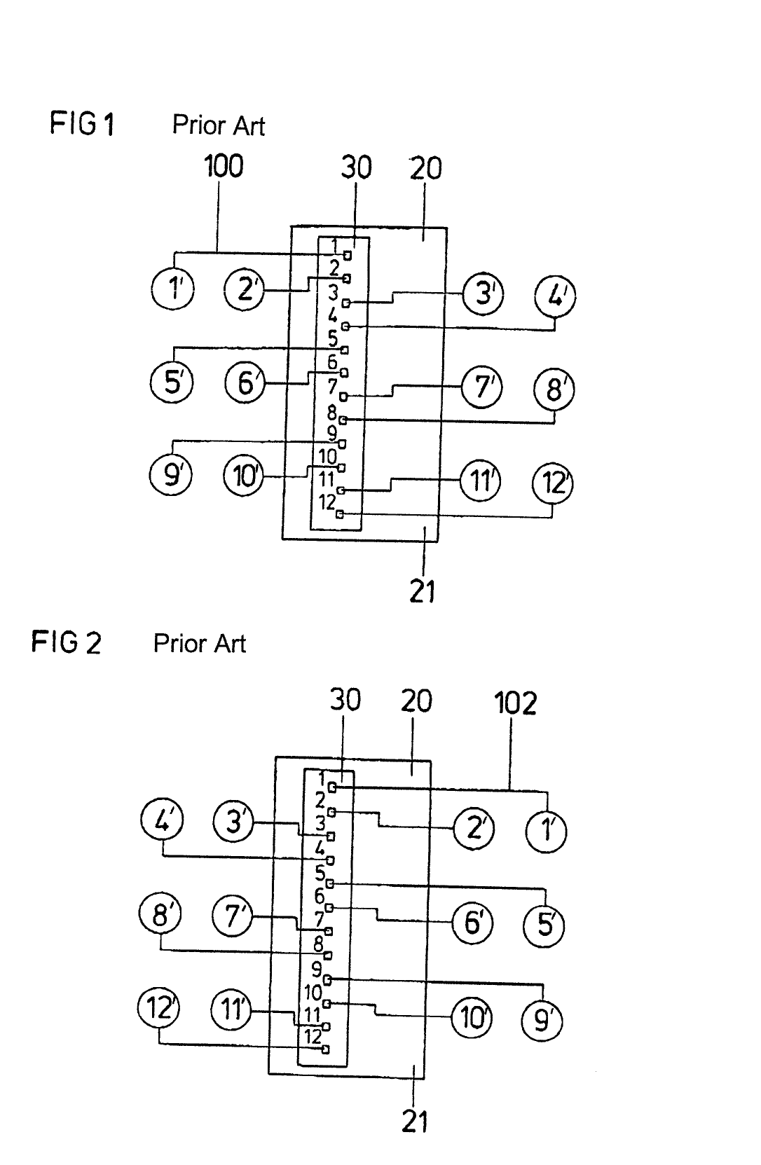

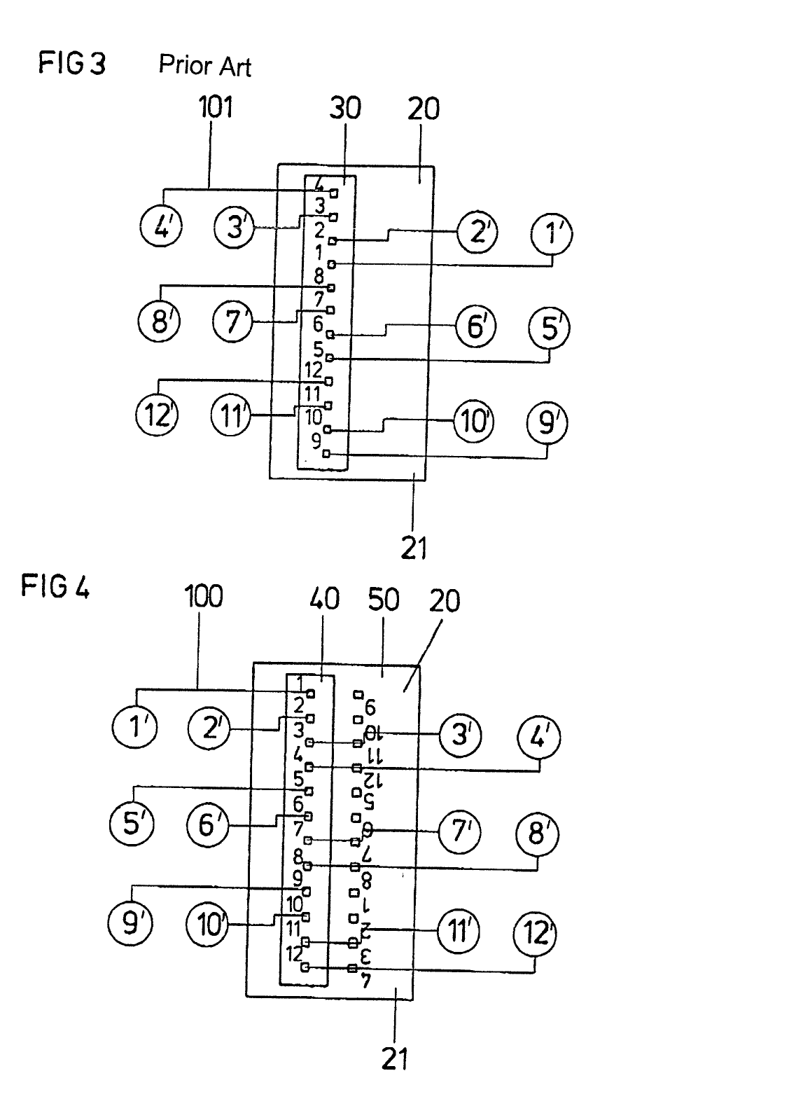

Referring now to the figures of the drawing in detail and first, particularly, to FIGS. 1-3 thereof, there are shown IC chips that are already known. A known example of this type is shown in FIGS. 1 to 3. In the case of the solution, a chip 20 is provided on its upper side 21 with (square) metallic bonding pads (“pads”) 1 to 12, which have a specific pin assignment, indicated by the numbering, and which are connected to a wiring 100 (FIG. 1), 102 (FIG. 2) or 101 (FIG. 3) of an interposer. The wirings 100, 101, 102 have at their free ends bonding points (“balls”), which are respectively assigned a number 1′ to 12′, which in each case corresponds to that of the associated bonding pads 1 to 12. The pin assignment of the individual bonding pads 1 to 12 on the upper side 21 of the IC chip 20 consequently corresponds exactly to the pin assignment of the corresponding bonding points 1′ to 12′ of the interposer wiring 100, 101, 102. The wiring is configured in such a way that the free bonding points 1′ to 12′ are disposed in pairs to the left and right of the IC chip 20. The configuration of the bonding points 1′ to 12′ in FIG. 1 shows a standard wiring or standard pin assignment with the pin assignments 1′, 2′, 5′, 6′, 9′, 10′ on one side of the IC chip 20 and the pin assignments 3′, 4′, 7′, 8′, 11′, 12′ on the opposite side of the IC chip 20. The configuration of the bonding points 1′ to 12′ in FIGS. 2 and 3 on the other hand respectively shows a mirror-image wiring or mirror-image pin assignment, which is mirror-inverted at a central axis of the IC chip 20 in comparison with the standard pin assignment according to FIG. 1 and runs parallel to the row of bonding pads 1 to 12 on the upper side 21 of the IC chip 20. The embodiment in FIG. 2 differs from that of FIG. 3 in that in FIG. 2 the layout of the IC chip 20 coincides with the layout of the chip 20 in FIG. 1 and the wiring layout 102 of the interposer in FIG. 2 has been changed in comparison with the wiring layout 100 in FIG. 1, whereas in FIG. 3 the wiring layout 101 of the interposer coincides with the wiring layout 102 of the interposer according to FIG. 2, while here in FIG. 3 the chip layout or the pin assignment of the bonding pads 1 to 12 (sequence in FIG. 3 from top to bottom: 4, 3, 2, 1, 8, 7, 6, 5, 12, 11, 10, 9) has been changed in comparison with the chip layout or the pin assignment of the bonding pads 1 to 12 in FIG. 1 (sequence in FIG. 1 from top to bottom: 1, 2, 3, 4, 5, 6, 7, 8, 9, 10, 11, 12). A disadvantage of the known solution is that the IC chips 20 have to be packaged in at least two configurations, that is in the standard configuration (FIG. 1) and at least in one configuration corresponding “mirror-invertedly” to it, the mirror-image configuration (FIG. 2 or FIG. 3). This increases the costs of producing such IC chips and makes it more difficult for PCBs to be fitted with such IC chips, since it must be strictly ensured when mounting the chips that the “correct” package chip, i.e. either the chip in the standard configuration or the chip in the mirror-image configuration, is selected in each case.

As already described above, the metallic bonding pads 1 to 12 are disposed in a row and are in each case connected to the wiring 100 or 101 or 102 of an interposer. The numbering of the bonding pads 1 to 12 stands for their pin assignment and is reflected in the identical numbering of the bonding points 1′ to 12′ at the free ends of the wiring 100 or 101 or 102 of the respective interposer. The wiring 100 in FIG. 1 represents a standard configuration, while the wirings 101 according to FIG. 3 and 102 according to FIG. 2 represent different mirror-image configurations in relation to the standard configuration. In comparison with the standard configuration in FIG. 1, in FIG. 2 the layout of the interposer has been changed, with an unchanged layout of the actual IC chip 20, whereas in FIG. 3 the layout of the IC chip 20 has been changed (see the sequence in the pin assignment of the bonding pads 1 to 12 on the IC chip 20 in FIG. 1 and FIG. 3) with an unchanged layout of the interposer.

FIGS. 4 and 5 both show the same IC chip 20, once with the wiring 100 in the standard configuration (FIG. 4) and once with the wiring 101 in the corresponding mirror-image configuration (FIG. 5) according to the invention.

The IC chip 20 has on the upper side 21 two groups 40 and 50 of metallic bonding pads 1 to 12, which are disposed in two rows lying next to each other. The two rows lie on two straight lines, which run parallel to each other and parallel to two of the four outer edges of the rectangular IC chip 20. Within a row, the bonding pads 1 to 12 all have the same spacing from the respectively directly neighboring bonding pads. The bonding pads 1 to 12 of the two rows lie in pairs on four straight lines, which run perpendicularly in relation to the two straight lines, and all have the same spacing—as a result of the parallelism of the two straight lines. The numbering, i.e. pin assignment, of the individual bonding pads 1 to 12 corresponds in the case of the first group 40 to the numbering of the bonding pads 1 to 12 of the IC chip 20 according to FIG. 1 (standard configuration: 1, 2,., 12), whereas the numbering, i.e. pin assignment, of the individual bonding pads of the second group 50 corresponds to the numbering of the bonding pads 1 to 12 of the IC chip 20 according to FIG. 3 (mirror-image configuration: 4, 3, 2, 1, 8, 7, 6, 5, 12, 11, 10, 9) and, in addition, also proceeds in opposite sequence in the row in comparison with the numbering of the first group 40.

The mirror-image configuration according to FIG. 5 is realized by the IC chip 20 being rotated, starting from its first position in relation to the wiring 100 according to FIG. 4, about the central axis perpendicularly in relation to the upper side 21 of the IC chip 20 through 180 degrees into its second position in relation to the wiring 101 according to FIG. 5. In the same way, the mirror-image configuration according to FIG. 5 can be transformed into the standard configuration according to FIG. 4 by rotation by 180 degrees about the central axis.

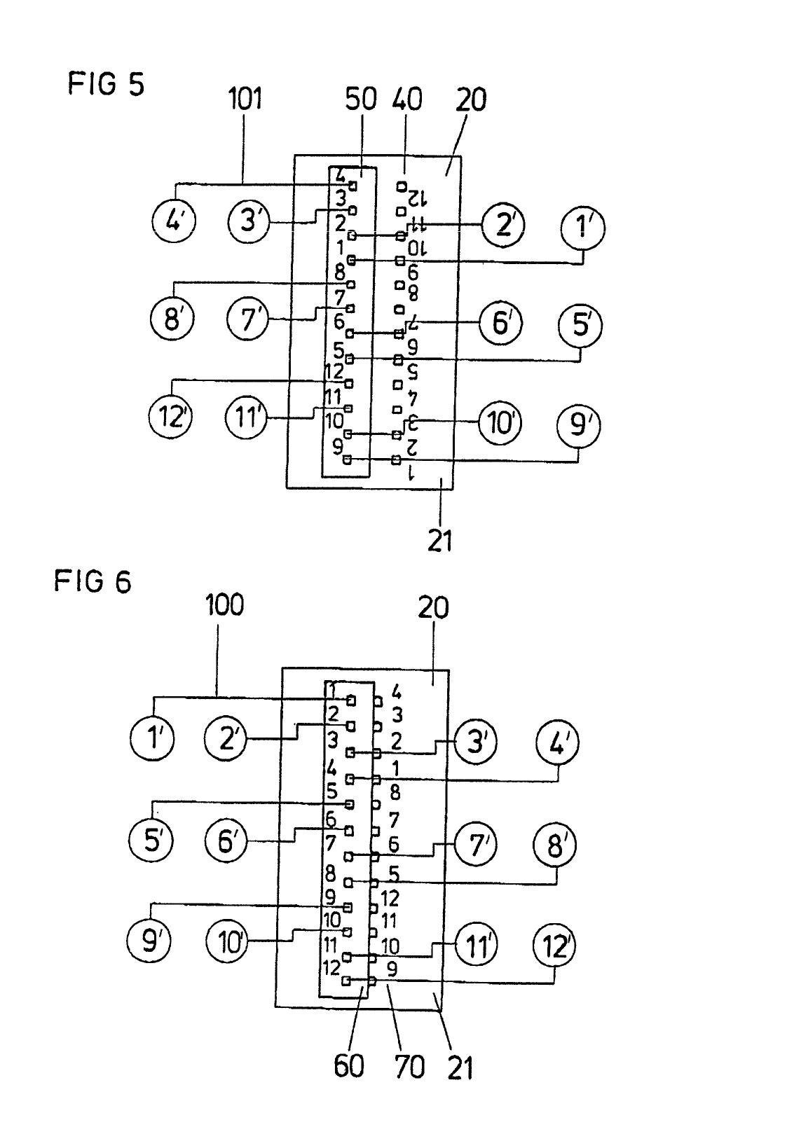

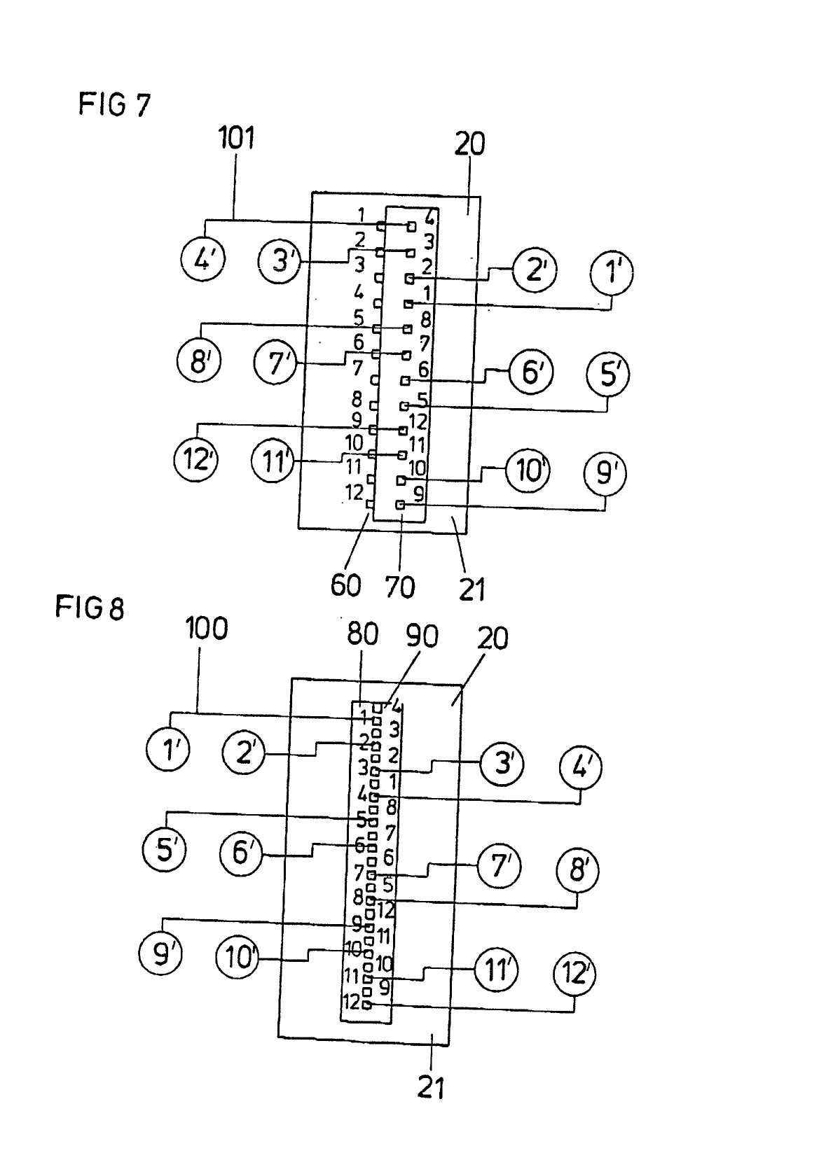

FIGS. 6 and 7 both show the same IC chip 20, once with the wiring 100 in the standard configuration (FIG. 6) and once in the corresponding mirror-image configuration 101 (FIG. 7). The difference with respect to the IC chip 20 according to FIGS. 4 and 5 is that, in the case of the IC chip 20 according to FIGS. 6 and 7, the numbering in the two groups 60 (standard configuration) and 70 (mirror-image configuration) of the bonding pads 1 to 12 proceeds in the same sense in both rows, i.e. here (by way of example) from top to bottom.

The mirror-image configuration according to FIG. 7 is realized by the IC chip 20 being displaced, starting from its first position in relation to the interposer wiring 100 according to FIG. 6, on a straight line parallel to the upper side 21 of the IC chip 20 and parallel to the fourth straight line, i.e. transversely in relation to the two rows of bonding pads 1 to 12, into its second position in relation to the interposer wiring 101 according to FIG. 7. In the same way, the mirror-image configuration according to FIG. 7 can be transformed into the standard configuration according to FIG. 6 by displacement along the straight line in the opposite direction.

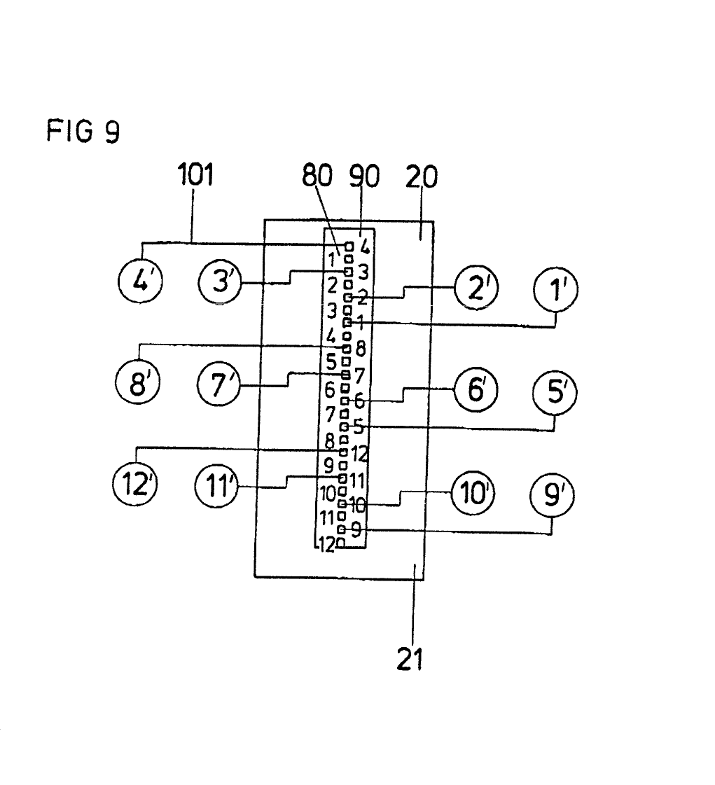

FIGS. 8 and 9 both show the same IC chip 20, once with wiring 100 in the standard configuration (FIG. 8) and once in the corresponding mirror-image configuration 101 (FIG. 9). The difference with respect to the IC chip 20 according to FIGS. 4 and 5 or 6 and 7 is that, in the case of the IC chip 20 according to FIGS. 8 and 9, the two groups 80 (standard configuration) and 90 (mirror-image configuration) of the bonding pads 1 to 12 are combined in a common row, which lies on a third straight line. In the common row, the bonding pads 1 to 12 alternately belong either to one or the other of the two groups 80 and 90, i.e. the individual numbers of the standard pin assignment 1, 2, 3, . . . 12 and those of the mirror-image pin assignment 4, 3, 2, 1, 8, 7, 6, 5, 12, 11, 10, 9 are interlinked here in one another and combined to form a common numbering 4, 1, 3, 2, 2, 3, 1, 4, 8, 5, 7, 6, 6, 7, 5, 8, 12, 9, 11, 10, 10, 11, 9, 12. The numbering also takes place here in the same sense, i.e. from top to bottom.

The mirror-image configuration according to FIG. 9 is realized by the IC chip 20 being displaced, starting from its first position in relation to the wiring 100 according to FIG. 8, on straight line parallel to the upper side 21 of the IC chip 20 and colinearly in relation to the third straight line, i.e. colinearly in relation to the common row of bonding pads 1 to 12 (doubled in number) into its second position in relation to the interposer wiring 101 according to FIG. 9. In the same way, the mirror-image configuration according to FIG. 9 can be transformed into the standard configuration according to FIG. 8 by displacement along the straight line in the opposite direction.

A major advantage of the three variants of the IC chip according to the invention is that, both for the standard configuration (FIG. 4; FIG. 6; FIG. 8) of the wiring and for the corresponding mirror-image configurations (FIG. 5; FIG. 7; FIG. 9), only one layout of the IC chip per variant and one (common) layout of the interposer wiring are required for all the variants.

A further advantage is that, by simple mounting measures (rotation of the chip by 180 degrees or a translational movement of the chip transversely or longitudinally in relation to the rows of bonding pads), the standard configuration can be transformed into the mirror-image configuration of the wiring, and vice versa.

The invention is not restricted to the exemplary embodiment represented, but rather can be transferred to other embodiments.

For example, it is possible instead of the configuration of the bonding pads on straight lines to select other linear configurations such as for example half- or quarter-circles, zigzag lines, arcs or other two-dimensional geometrical configurations such as circles, triangles, rectangles and other polygons, etc.; all that is necessary is to ensure that the required bonding pads on the upper side or underside of the chip are on the one hand provided at least twice (that is in standard configuration and in mirror-image configuration) and that on the other hand the chosen configurations of the bonding pads meet the rotational-symmetrical or translational-symmetrical requirements during the placement of these configurations on the bonding pads on the upper side or underside of the chip. In the case of the required rotational symmetry, the bonding pads may lie, for example, on a common circle with the axis of rotation as the center point. The bonding pads of one group (standard configuration) may in this case lie on one of the two halves of the circle and the bonding pads of the other group (mirror-image configuration) may lie on the other half. It is also conceivable, however, in a way similar to the solution according to FIGS. 8 and 9, for the bonding pads to be disposed in equal distribution on the circle and alternately originating from the two groups, so that all that is required for the transformation of the standard configuration of the wiring into the corresponding mirror-image configuration of the wiring is a rotation by 360 degrees/n, where n is the number of bonding pads of one group.

Furthermore, it is possible to configure the vertical electrical assignment, i.e. the vertical position, correspondingly by a metal fix or by fuses. The major advantage of such a solution is that only one mask has to be changed and that the number of bonding pads (and consequently the space requirement) is lower than in the case of doubling the bonding pads.

We claim:

1. An integrated circuit (IC) chip, comprising:
a chip body having an upper side and an under side, said chip body able to be connected optionally to one of a standard wiring configuration for a standard pin assignment and to a mirror-image wiring configuration for a mirror-image pin assignment, the mirror-image wiring configuration being mirror-inverted in relationship to the standard wiring configuration; and
at least two groups of metallic bonding pads disposed on one of said upper side and said under side of said chip body, a first group of said at least two groups of said metallic bonding pads ordered in the standard pin assignment, a second group of said at least two groups of said metallic bonding pads ordered in the mirror-image pin assignment.

2. The IC chip according to claim 1, wherein given the standard wiring configuration for the standard pin assignment and the mirror-image wiring configuration for the mirror-image pin assignment, the standard pin alignment is realized by a positioning of said chip body in a first position, the mirror-image pin assignment realized by a positioning of said chip body in a second position and once in the second position can be transformed into the first position by rotation of said chip body about an axis aligned perpendicularly in relation to said upper side or said underside of said chip body or by a translational movement of said chip body along a straight line, running parallel to said upper side or to said underside of said chip body.

3. The IC chip according to claim 2, wherein for a transformation from the second position into the first position, and vice versa, in each case, rotating said IC chip body by one of 90°, 180° and 270° is required.

4. The IC chip according to claim 2, wherein said standard wiring configuration and said mirror-image wiring configuration in each case extends on two opposite sides of said chip body over said chip body.

5. The IC chip according to claim 2, wherein said first group of said metallic bonding pads is disposed in a first row and said second group of said metallic bonding pads is disposed in a second row on said chip body.

6. The IC chip according to claim 5, wherein said first row and said second row are disposed next to each other.

7. The IC chip according to claim 5, wherein said metallic bonding pads of said first row and said metallic bonding pads of said second row have within their own row, in each case, a same spacing in relation to directly neighboring bonding pads.

8. The IC chip according to claim 5, wherein said metallic bonding pads of said first row and said metallic bonding pads of said second row each lie along one of two straight lines running parallel to each other.

9. The IC chip according to claim 8, wherein said metallic bonding pads in said first row and said metallic bonding pads in said second row lie directly opposite one another and in each case lie along a further straight line, running perpendicularly in relation to the two straight lines.

10. The IC chip according to claim 5, wherein pins of said standard pin assignment of said metallic bonding pads of said first group along said first row are assigned in a same direction as pins of the mirror-image pin assignment of said metallic bonding pads of said second group.

11. The IC chip according to claim 5, wherein for a transformation from the second position of said chip body into the first position, and vice versa, in each case a translational movement transversely in relation to said first and second rows is required.

12. The IC chip according to claim 1, wherein said metallic bonding pads of said first group and of said second group are disposed in an alternating manner in a common row.

13. The IC chip according to claim 12, wherein said metallic bonding pads of said first group and of said second group in said common row have in each case a same spacing in relation to directly neighboring bonding pads of the other group respectively.

14. The IC chip according to claim 12, wherein pins of said standard pin assignment of said metallic bonding pads of said first group and pins of said mirror-image pin assignment of said metallic bonding pads of said second group both lying along said common row are assigned in a same direction.

15. The IC chip according to claim 5, wherein pins of said standard pin assignment of said metallic bonding pads of said first group along said first row are assigned in an opposite direction than pins of said mirror-image pin assignment of said metallic bonding pads of said second group.

16. The IC chip according to claim 12, wherein for a transformation from the second position of said chip body to the first position, and vice versa, in each case a translational movement along said common row is required.

17. The IC chip according to claim 12, wherein said metallic bonding pads of said first group and of said second group lying in said common row lie along a straight line.

18. A component placement method, which comprises the steps of:
providing an integrated circuit chip containing a chip body having an upper side and an under side, the chip body able to be connected optionally to one of a standard wiring configuration for a standard pin assignment and to a mirror-image wiring configuration for a mirror-image pin assignment, the mirror-image wiring configuration being mirror-inverted in relationship to the standard wiring configuration, at least two groups of metallic bonding pads disposed on one of the upper side and the under side of the chip body, a first group of the at least two groups of the metallic bonding pads ordered in the standard pin assignment, a second group of the at least two groups of the metallic bonding pads ordered in the mirror-image pin assignment; and
using the integrated circuit for placing components on at least one side of a printed circuit board using surface mounting techniques.
